(19) United States
(12) Patent Application Publication
(10) Pub. No.: US 2025/0120257 A1
(43) Pub. Date: Apr. 10, 2025

(54) METHOD OF MANUFACTURING DISPLAY DEVICE

(71) Applicant: Samsung Display Co., Ltd., Yongin-si (KR)

(72) Inventors: Jeongmoon Lee, Yongin-si (KR); Daehong Kim, Yongin-si (KR)

(21) Appl. No.: 18/808,722

(22) Filed: Aug. 19, 2024

(30) Foreign Application Priority Data
Oct. 4, 2023 (KR) 10-2023-0131933

(51) Int. Cl. H10K 59/12; H10K 59/80

(52) U.S. Cl. CPC H10K 59/1201; H10K 59/873

(57) ABSTRACT

A method of manufacturing a display device is provided. The method includes: applying an organic encapsulation layer to a substrate of the display device, the substrate having a display area and a peripheral area extending at least partially around the display area; irradiating light to the organic encapsulation layer; and capturing an image of the peripheral area to which the organic encapsulation layer is applied.

### CROSS-REFERENCE TO RELATED APPLICATION

This application claims priority to and the benefit of Korean Patent Application No. 10-2023-0131933, filed on Oct. 4, 2023, in the Korean Intellectual Property Office, the present disclosure of which is incorporated by reference herein in its entirety.

### BACKGROUND

### 1. Field

Aspects of embodiments of the present disclosure relate to a method of manufacturing a display device.

### 2. Description of the Related Art

Display devices visually display data. Display devices may provide (e.g., may display) images by using light-emitting diodes. The usage of display devices has diversified, and a variety of designs to improve the quality of display devices have been attempted.

### SUMMARY

Embodiments of the present disclosure include a method of manufacturing a display device.

Additional aspects and features of the present disclosure will be set forth, in part, in the description which follows and, in part, will be apparent from the description or may be learned by practice of the embodiments of the present disclosure described below.

According to an embodiment of the present disclosure, a method of manufacturing a display device includes: applying an organic encapsulation layer to a substrate of the display device, the substrate having a display area and a peripheral area extending at least partially around the display area; irradiating light to the organic encapsulation layer; and capturing an image of the peripheral area to which the organic encapsulation layer is applied.

The method may further include, after the capturing of the image of the peripheral area, estimating an application amount of the organic encapsulation layer applied to the peripheral area.

In the irradiating of the light to the organic encapsulation layer, the organic encapsulation layer to which the light is irradiated may become opaque.

An application amount of the organic encapsulation layer may be estimated according to a degree of opacity of the organic encapsulation layer to which the light is irradiated.

A degree of opacity of the organic encapsulation layer may vary according to a thickness of the organic encapsulation layer that is applied.

As a thickness of the organic encapsulation layer that is applied increases, the degree of opacity of the organic encapsulation layer may increase.

The light may have a wavelength range in an ultraviolet region.

The wavelength range of the light may be from 365 nm to 395 nm.

The display device may include a first dam in the peripheral area.

The display device may have a recess in the peripheral area between the first dam and the display area.

The display device may further include a second dam in the peripheral area and further away from the display area than the first dam is.

In the applying of the organic encapsulation layer to the substrate, the organic encapsulation layer may be filled in the recess.

An area of a cross-section of the recess parallel to the substrate may decrease in a direction toward the substrate.

A cross-sectional length of the recess in a first direction may uniformly decrease in a direction toward the substrate.

The recess may have an island shape.

The recess may have a linear shape and may extend parallel to an edge of the display area.

A cross-sectional area of the recess parallel to the substrate may be constant in a direction perpendicular to the substrate.

A cross-sectional length of the recess in a first direction may be constant.

The recess may have an island shape.

The recess may have a linear shape and may extend parallel to an edge of the display area.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic plan view of a display device according to an embodiment;

FIG. 2 is a schematic equivalent circuit diagram of a sub-pixel circuit in the display device shown in FIG. 1 according to an embodiment;

FIG. 3 is a schematic cross-sectional view of the display device taken along the line I-I′ in FIG. 1;

FIGS. 4 and 5 are images with schematic overlays showing a peripheral area of a display device according to different embodiments;

FIG. 6 is a schematic cross-sectional view of the peripheral areas of the display devices taken along the line II-II′ in FIGS. 4 and 5;

FIGS. 7 and 8 are images with schematic overlays showing organic encapsulation layers applied to peripheral areas of display devices according to different embodiments;

FIGS. 9 and 10 are images with schematic overlays showing peripheral areas of display devices according to different embodiments;

FIG. 11 is a schematic cross-sectional view of the peripheral areas of the display devices taken along the line III-III′ in FIGS. 9 and 10; and

FIGS. 12 and 13 are images with schematic overlays showing organic encapsulation layers applied to peripheral areas of display devices according to different embodiments.

### DETAILED DESCRIPTION

Reference will now be made, in detail, to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Hereinafter, embodiments will be described in detail with reference to the accompanying drawings, and in the description with reference to the drawings, the same or corresponding constituents are indicated by the same reference numerals and redundant descriptions thereof are omitted.

In the following embodiment, it will be understood that although the terms first, second, etc. may be used herein to describe various elements, these elements should not be limited by these terms. These terms are only used to distinguish one element from another.

In the following embodiment, as used herein, the singular forms “a” and “an” are intended to include the plural forms as well, unless the context clearly indicates otherwise.

It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

In the figures, dimensions of the various elements, layers, etc. may be exaggerated for clarity of illustration. The same reference numerals designate the same elements.

When a certain embodiment may be implemented differently, a specific process order may be performed differently from the described order. For example, two consecutively described processes may be performed substantially at the same time or performed in an order opposite to the described order.

Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

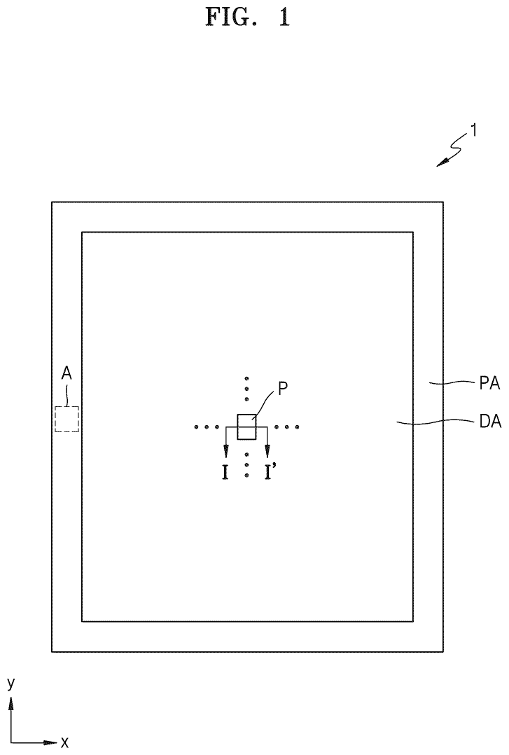

FIG. 1 is a schematic plan view of a display device 1 according to an embodiment.

Referring to FIG. 1, the display device 1 may have a display area DA and a peripheral area PA arranged outside of (e.g., around a periphery of) the display area DA. The display area DA may display an image through sub-pixels P arranged in the display area DA. The peripheral area PA is arranged outside of the display area DA and, as a non-display area that does not display an image, may entirely surround (e.g. may extend entirely around a periphery of or may entirely surround in a plan view) the display area DA. Drivers for providing electrical signals or power to the display area DA and the like may be arranged in the peripheral area PA. A pad, which is an area to which electronic components, printed circuit boards, and the like are electrically connected, may be arranged in the peripheral area PA.

FIG. 1 illustrates an embodiment in which the display area DA is a polygon (e.g., a quadrangle) shape in which the length of the display area DA in an x direction is relatively less than the length thereof in a y direction, but the present disclosure is not limited thereto. In another embodiment, the display area may have a different polygonal (e.g., a quadrangle) shape in which the length of the display area DA in the y direction is relatively less than the length thereof in the x direction. Although FIG. 1 illustrates an embodiment in which the display area DA is approximately quadrangular, the present disclosure is not limited thereto. In other embodiments, the display area DA may have various shapes, such as an N-gon (N is a natural number of 3 or more), a circle, an oval, and the like. Although FIG. 1 illustrates an embodiment in which the display area DA has a corner portion that includes a vertex where a straight line meets another straight line, in another embodiment, the display area DA may have a polygonal shape with rounded corner portions.

In the following description, for convenience of explanation, an embodiment in which the display device 1 is an electronic device, such as a smart phone, is described, but the display device 1 is not limited thereto. The display device 1 may be applied to various products including not only portable electronic devices, such as mobile phones, smart phones, tablet personal computers (PCs), mobile communication terminals, electronic organizers, electronic books, portable multimedia players (PMPs), navigation devices, ultra-mobile PCs (UMPCs), and the like, but also televisions, notebook computers, monitors, billboards, Internet of Things (IoT) devices, and the like. Furthermore, the display device 1, according to an embodiment, may be applied to wearable devices, such as smart watches, watch phones, glasses type displays, and head mounted displays (HMDs). Furthermore, the display device 1, according to an embodiment, may be used as an instrument panel of a vehicle, a center information display (CID) disposed in the center fascia or dashboard of a vehicle, a room (or in-car) mirror display in lieu of a side mirror of a vehicle, or a display screen disposed at the rear surface of a front seat as an entertainment device for a rear seat of a vehicle.

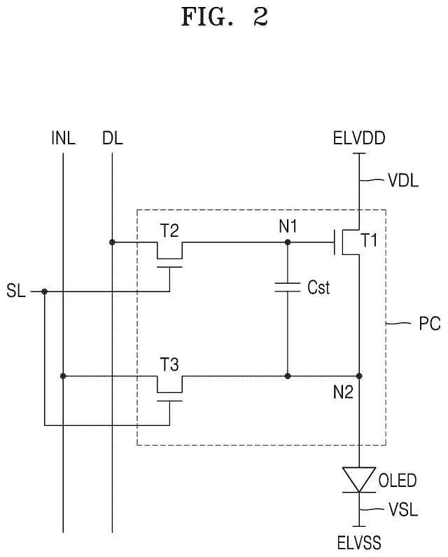

FIG. 2 is a schematic equivalent circuit diagram of a sub-pixel circuit provided in the display device shown in FIG. 1 according to an embodiment.

Referring to FIG. 2, a sub-pixel circuit PC may include a plurality of thin film transistors and at least one capacitor. In an embodiment, the sub-pixel circuit PC may include a first thin film transistor T1, a second thin film transistor T2, a third thin film transistor T3, and a storage capacitor Cst.

Each of the first thin film transistor T1, the second thin film transistor T2, and the third thin film transistor T3 may be an oxide semiconductor thin film transistor including a semiconductor layer formed of an oxide semiconductor or may be a silicon semiconductor thin film transistor including a semiconductor layer formed of polysilicon. Each thin film transistor may include a first electrode and a second electrode, and according to the type of thin film transistor, the first electrode may be one of a source electrode and a drain electrode, and the second electrode may be the other of the source electrode and the drain electrode. Furthermore, each thin film transistor may include a gate electrode.

The first thin film transistor T1 may be a driving thin film transistor. The first electrode of the first thin film transistor T1 may be connected to a driving voltage line VDL for providing a driving power voltage ELVDD, and the second electrode thereof may be connected to a pixel electrode of an organic light-emitting diode OLED. The gate electrode of the first thin film transistor T1 may be connected to a first node N1. The first thin film transistor T1 may control, in response to the voltage of the first node N1, the amount of current flowing from the driving power voltage ELVDD to the organic light-emitting diode OLED.

The second thin film transistor T2 may be a switching thin film transistor. The first electrode of the second thin film transistor T2 may be connected to a data line DL, and the second electrode thereof may be connected to the first node N1. The gate electrode of the second thin film transistor T2 may be connected to a scan line SL. The second thin film transistor T2 may be turned on when a scan signal is supplied to the scan line SL to electrically connect the data line DL to the first node N1.

The third thin film transistor T3 may be an initialization thin film transistor and/or a sensing thin film transistor. The first electrode of the third thin film transistor T3 may be connected to a second node N2, and the second electrode thereof may be connected to an initialization voltage line INL. The gate electrode of the third thin film transistor T3 may be connected to the scan line SL.

The third thin film transistor T3 may be turned on when the scan signal is supplied to the scan line SL to electrically connect the initialization voltage line INL to the second node N2. In some embodiments, the third thin film transistor T3 may be turned on in response to a signal received through the scan line SL to initialize the pixel electrode of the organic light-emitting diode OLED with an initialization voltage from the initialization voltage line INL.

In some embodiments, the third thin film transistor T3 may be turned on when the scan signal is supplied to the scan line SL to sense characteristic information of the organic light-emitting diode OLED. The third thin film transistor T3 may act as both or as one of the initialization thin film transistor and the sensing thin film transistor. The initialization operation and sensing operation of the third thin film transistor T3 may be individually or concurrently (or simultaneously) performed. When the third thin film transistor T3 acts as the sensing thin film transistor, the initialization voltage line INL may be referred to as a sensing line.

The storage capacitor Cst may be connected between the first node N1 and the second node N2. For example, a first capacitor plate CE1 of the storage capacitor Cst may be connected to the gate electrode of the first thin film transistor T1, and a second capacitor plate CE2 of the storage capacitor Cst may be connected to the pixel electrode of the organic light-emitting diode OLED.

A counter electrode of the organic light-emitting diode OLED may be connected to a common voltage line VSL for suppling a common power voltage ELVSS.

Although FIG. 2 illustrates an embodiment in which the sub-pixel circuit PC includes three thin film transistors and one storage capacitor, the present disclosure is not limited thereto. In other embodiments, the number of thin film transistors and/or the number of storage capacitors may be variously changed according to the design of the sub-pixel circuit PC.

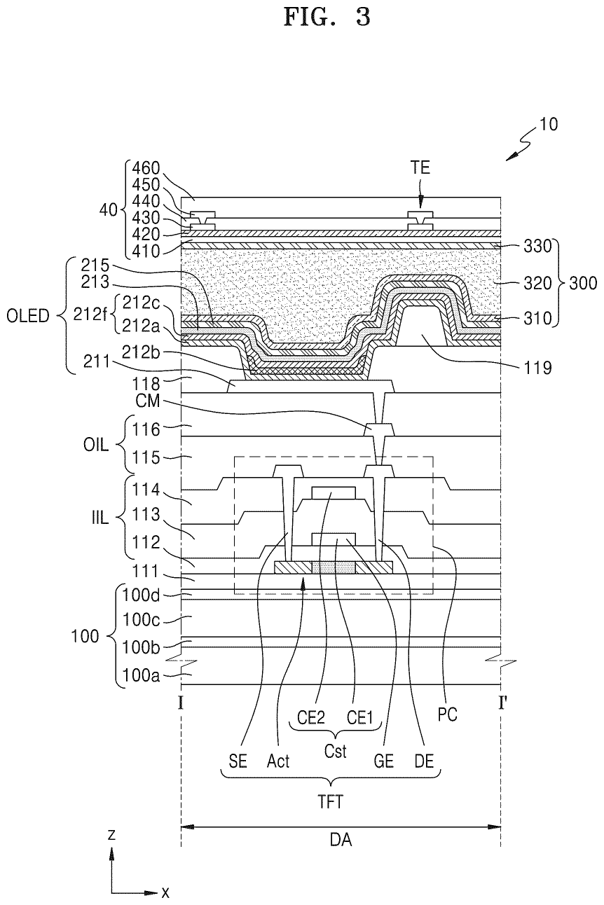

FIG. 3 is a schematic cross-sectional view of the display device 1 taken along the line I-I′ in FIG. 1.

Referring to FIG. 3, the display panel 10 may include a substrate 100, an inorganic insulating layer IIL, an organic insulating layer OIL, the sub-pixel circuit PC, a connection electrode CM, the organic light-emitting diode OLED, a pixel defining layer 118, a spacer 119, and an encapsulation layer 300. The substrate 100, the inorganic insulating layer IIL, the organic insulating layer OIL, the sub-pixel circuit PC, the connection electrode CM, the organic light-emitting diode OLED, the pixel defining layer 118, the spacer 119, and the encapsulation layer 300 may be disposed in the display area DA of the display panel 10.

The substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction of the substrate 100.

At least one of the first base layer 100a and the second base layer 100c may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, and the like.

The first barrier layer 100b and the second barrier layer 100d, as barrier layers for preventing infiltration of external foreign materials, may be a single layer or a multilayer structure including an inorganic material, such as a silicon nitride (SiNₓ), a silicon oxide (e.g., SiO₂), and/or a silicon oxynitride (SiON).

A buffer layer 111 may be disposed on the substrate 100. The buffer layer 111 may include an inorganic insulating material, such as SiNₓ, SiON, and SiO₂, and may be a single layer or a multilayer structure including the inorganic insulating material(s) described above.

The inorganic insulating layer IIL may be disposed on the buffer layer 111. The inorganic insulating layer IIL may include a first gate insulating layer 112, a second gate insulating layer 113, and an interlayer insulating layer 114.

The sub-pixel circuit PC may be arranged in the display area DA. The sub-pixel circuit PC may include a thin film transistor TFT and the storage capacitor Cst. The thin film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. In other embodiments, the semiconductor layer Act may include amorphous silicon, an oxide semiconductor, an organic semiconductor, and the like. The semiconductor layer Act may include a channel region and a drain region and a source region arranged at opposite sides of the channel region.

The gate electrode GE may be disposed on the semiconductor layer Act. The gate electrode GE may overlap the channel region. The gate electrode GE may include a low resistance metal material. The gate electrode GE may include a conductive material, such as molybdenum (Mo), aluminum (AI), copper (Cu), titanium (Ti), and the like, and may be formed in as a multilayer structure or in single layer including the material(s) described above.

The first gate insulating layer 112 may be arranged between the semiconductor layer Act and the gate electrode GE. The first gate insulating layer 112 may include an inorganic insulating material, such as SiO₂, SiNₓ, SiON, an aluminum oxide (e.g., Al₂O₃), a titanium oxide (e.g., TiO₂), a tantalum oxide (e.g., Ta₂O₅), a hafnium oxide (e.g., HfO₂), a zinc oxide (e.g., ZnO), or the like.

The second gate insulating layer 113 may be disposed on the gate electrode GE. The second gate insulating layer 113 may be provided to cover the gate electrode GE. The second gate insulating layer 113 may include an inorganic insulating material, such as SiO₂, SiNₓ, SiON, Al₂O₃, TiO₂, Ta₂O₅, HfO₂, ZnO, or the like.

The second capacitor plate CE2 of the storage capacitor Cst may be disposed on the second gate insulating layer 113. The second capacitor plate CE2 may overlap the gate electrode GE disposed thereunder. In this arrangement, the gate electrode GE and the second capacitor plate CE2 overlap each other with the second gate insulating layer 113 therebetween to form the storage capacitor Cst. In other words, the gate electrode GE may act as the first capacitor plate CE1 of the storage capacitor Cst.

As such, the storage capacitor Cst and the thin film transistor TFT may be formed to overlap each other (e.g., to overlap each other in a thickness direction of the display device 1). However, the present disclosure is not limited thereto. For example, the storage capacitor Cst may be formed not to overlap (e.g., to be offset from) the thin film transistor TFT. In such an embodiment, the first capacitor plate CE1 of the storage capacitor Cst may be formed as a separate component from the gate electrode GE of the thin film transistor TFT and may be provided spaced apart from the gate electrode GE of the thin film transistor TFT.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a multilayer structure including the material(s) described above.

The interlayer insulating layer 114 may be disposed on the second capacitor plate CE2. The interlayer insulating layer 114 may cover the second capacitor plate CE2. The interlayer insulating layer 114 may include SiO₂, SiNₓ, SiON, Al₂O₃, TiO₂, Ta₂O₅, HfO₂, or ZnO, and the like. The interlayer insulating layer 114 may be a single layer or a multilayer structure including the inorganic insulating material(s) described above.

The drain electrode DE and the source electrode SE may each be disposed on the interlayer insulating layer 114. The drain electrode DE and the source electrode SE may each be connected to the semiconductor layer Act through a contact hole (e.g., a contact opening) in the first gate insulating layer 112, the second gate insulating layer 113, and the interlayer insulating layer 114. The drain electrode DE and the source electrode SE may each include a material with relatively high conductivity. The drain electrode DE and the source electrode SE may each include a conductive material, such as Mo, Al, Cu, Ti, and the like, and may each be formed in as a multilayer structure or as single layer including the material(s) described above. For example, the drain electrode DE and the source electrode SE may each have a multilayer structure of Ti/Al/Ti.

The organic insulating layer OIL may be disposed on the inorganic insulating layer IIL. The organic insulating layer OIL may include a first organic insulating layer 115 and a second organic insulating layer 116. Although FIG. 3 illustrates an embodiment in which the organic insulating layer OIL includes two organic insulating layers, the present disclosure is not limited thereto. In other embodiments, the organic insulating layer OIL may include three or four organic insulating layers.

The first organic insulating layer 115 may cover the drain electrode DE and the source electrode SE. The first organic insulating layer 115 may include an organic insulating material, such as a general purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The connection electrode CM may be disposed on the first organic insulating layer 115. The connection electrode CM may be connected to the drain electrode DE or the source electrode SE through a contact hole (e.g., a contact opening) in the first organic insulating layer 115. The connection electrode CM may include a material with relatively high conductivity. The connection electrode CM may include a conductive material, such as Mo, Al, Cu, Ti, and the like, and may be formed in as a multilayer structure or in a single layer including the material(s) described above. For example, the connection electrode CM may have a multilayer structure of Ti/Al/Ti.

The second organic insulating layer 116 may be disposed on the connection electrode CM. The second organic insulating layer 116 may cover the connection electrode CM. The second organic insulating layer 116 may include the same material as or a different material from the material of the first organic insulating layer 115.

A light-emitting diode may be disposed on the second organic insulating layer 116. For example, the organic light-emitting diode OLED may be disposed on the second organic insulating layer 116. In another embodiment, an inorganic light-emitting diode and the like may be disposed on the second organic insulating layer 116.

The organic light-emitting diode OLED may emit red, green, or blue light, or red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be a counter electrode (e.g., a cathode) of the organic light-emitting diode OLED.

The first electrode 211 may be disposed on the second organic insulating layer 116. The first electrode 211 may be electrically connected to the connection electrode CM through a contact hole (e.g., a contact opening) defined in the second organic insulating layer 116. The first electrode 211 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In an embodiment, the first electrode 211 may include a reflective film including Ag, Mg, Al, Pt, Pd, Au, Ni, Nd, Ir, Cr, or a compound thereof. In an embodiment, the first electrode 211 may further include a film formed of ITO, IZO, ZnO, or In₂O₃ above and/or below the reflective film described above. For example, the first electrode 211 may have a multilayer structure of ITO/Ag/ITO.

A pixel defining layer 118, in which an opening for exposing at least a part of the first electrode 211 is defined, may be disposed on the first electrode 211. An emission area of light emitted from the organic light-emitting diode OLED may be defined by the opening defined in the pixel defining layer 118. For example, the width of the opening in the pixel defining layer 118 may correspond to the width of the emission area.

The pixel defining layer 118 may include an organic insulating material. In another embodiment, the pixel defining layer 118 may include an inorganic insulating material, such as a silicon nitride, a silicon oxynitride, or a silicon oxide. In another embodiment, the pixel defining layer 118 may include an organic insulating material and an inorganic insulating material. In an embodiment, the pixel defining layer 118 may include a light blocking material. The light blocking material may include carbon black, carbon nanotube, resin or paste including a black dye, metal particles such as nickel, aluminum, molybdenum, and an alloy thereof, metal oxide particles (e.g., a chromium oxide), metal nitride particles (e.g., a chromium nitride), or the like. When the pixel defining layer 118 includes the light blocking material, external light reflection due to metal structures arranged below the pixel defining layer 118 may be reduced.

The spacer 119 may be disposed on the pixel defining layer 118. The spacer 119 may include an organic insulating material, such as polyimide. In another embodiment, the spacer 119 may include an inorganic insulating material, such as SiNₓ or SiO₂, or an organic insulating material and an inorganic insulating material.

In an embodiment, the spacer 119 may include the same material as the material of the pixel defining layer 118. In such an embodiment, the pixel defining layer 118 and the spacer 119 may be formed together in a mask process by using a half tone mask and the like. In another embodiment, the spacer 119 and the pixel defining layer 118 may include different materials from each other.

The emission layer 212b may be arranged in the opening in the pixel defining layer 118. The emission layer 212b may include a polymer or low molecular weight organic material configured to emit light of a certain color.

The functional layer 212f may include a first functional layer 212a and a second functional layer 212c. The first functional layer 212a may be arranged between the first electrode 211 and the emission layer 212b, and the second functional layer 212c may be arranged between the emission layer 212b and the second electrode 213. However, in some embodiments, at least one of the first functional layer 212a or the second functional layer 212c may be omitted. In the following description, an embodiment including both the first functional layer 212a and the second functional layer 212c is primarily described.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c, similar to the second electrode 213, to be described below, may be common layers formed to entirely cover the substrate 100.

The second electrode 213 may be disposed on the functional layer 212f. The second electrode 213 may include a conductive material having a low work function. For example, the second electrode 213 may include a (semi-) transparent layer including Ag, Mg, Al, Pt, Pd, Au, Ni, Nd, Ir, Cr, lithium (Li), Ca, or an alloy thereof, and the like. In some embodiments, the second electrode 213 may further include a layer including ITO, IZO, ZnO, or In₂O₃ on the (semi-) transparent layer including the material described above.

In an embodiment, the capping layer 215 may be disposed on the second electrode 213. The capping layer 215 may include lithium fluoride (LiF), an inorganic material, or/and an organic material.

The encapsulation layer 300 may be disposed on the organic light-emitting diode OLED. The encapsulation layer 300 may cover the organic light-emitting diode OLED. The encapsulation layer 300 may be disposed on the second electrode 213 and/or the capping layer 215. In an embodiment, the encapsulation layer 300 may include at least one inorganic encapsulation layer and at least one organic encapsulation layer. FIG. 3 illustrates an embodiment in which the encapsulation layer 300 includes a first inorganic encapsulation layer 310, an organic encapsulation layer 320, and a second inorganic encapsulation layer 330, which are sequentially stacked o each other.

The first inorganic encapsulation layer 310 and the second inorganic encapsulation layer 330 may each include one or more inorganic materials of an aluminum oxide, a titanium oxide, a tantalum oxide, a hafnium oxide, a zinc oxide, a silicon oxide, a silicon nitride, and a silicon oxynitride. The first inorganic encapsulation layer 310 and the second inorganic encapsulation layer 330 may each be a single layer or a multilayer structure including the material(s) described above. The organic encapsulation layer 320 may include a polymer-based material. The polymer-based material may include a resin, an epoxy-based resin, polyimide, polyethylene, and the like. In an embodiment, the organic encapsulation layer 320 may include acrylate.

An input detection layer 40 may be disposed on the encapsulation layer 300. The input detection layer 40 may include a first touch insulating layer 410, a second touch insulating layer 420, a first conductive layer 430, a third touch insulating layer 440, a second conductive layer 450, and a planarization layer 460.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may each include an inorganic insulating material and/or an organic insulating material. For example, the first touch insulating layer 410 and the second touch insulating layer 420 may each include an inorganic insulating material, such as a silicon oxide, a silicon nitride, and/or a silicon oxynitride.

In an embodiment, at least one of the first touch insulating layer 410 and the second touch insulating layer 420 may be omitted. For example, the first touch insulating layer 410 may be omitted. In such an embodiment, the second touch insulating layer 420 may be disposed on the second inorganic encapsulation layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In an embodiment, the third touch insulating layer 440 may include an inorganic insulating material and/or an organic insulating material. For example, the third touch insulating layer 440 may include an inorganic insulating material, such as a silicon oxide, a silicon nitride, and/or a silicon oxynitride.

The second conductive layer 450 may be disposed on the third touch insulating layer 440. A touch electrode TE of the input detection layer 40 may have a structure in which the first conductive layer 430 is connected to the second conductive layer 450. In another embodiment, the touch electrode TE may be formed on any one layer of the first conductive layer 430 and the second conductive layer 450 and may include a metal line provided on the corresponding conductive layer. The first conductive layer 430 and the second conductive layer 450 may each include at least one of Al, Cu, Ti, Mo, and ITO and may each be in a single layer or may have a multilayer structure including the material described above. For example, the first conductive layer 430 and the second conductive layer 450 may each have a three-layer structure of a titanium layer/an aluminum layer/a titanium layer.

In an embodiment, the planarization layer 460 may cover the second conductive layer 450. The planarization layer 460 may include an organic insulating material.

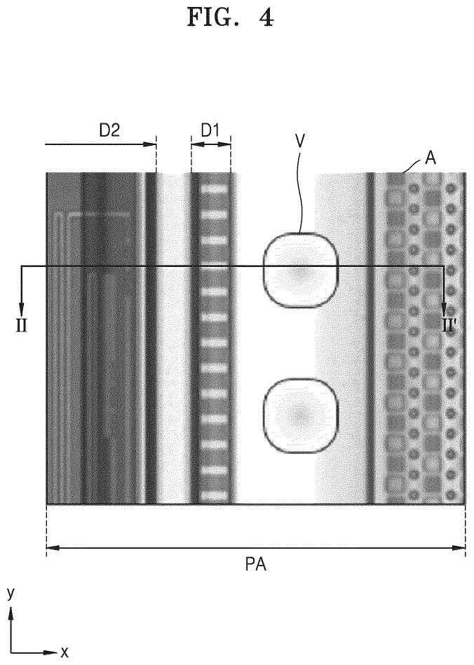

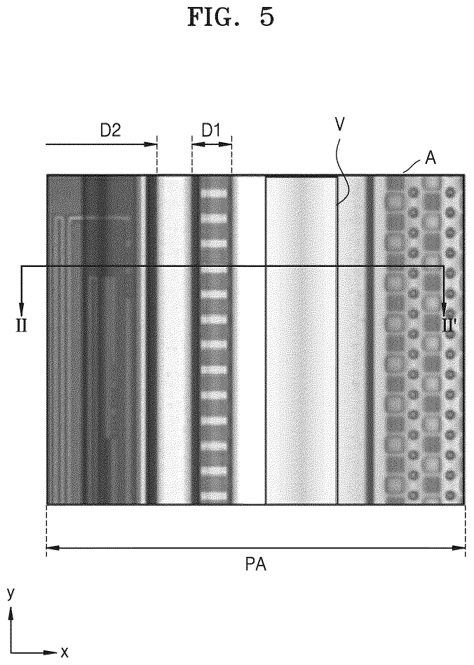

FIGS. 4 and 5 are images with schematic overlays showing an area A of the peripheral area PA of the display device 1 shown in FIG. 1.

Referring to FIGS. 4 and 5, a first dam D1 may be arranged in the peripheral area PA of the display device 1. The first dam D1 may be arranged along and parallel to the edge of the display area DA shown in FIG. 1.

A second dam D2 may be arranged in the peripheral area PA of the display device 1. The second dam D2 may be arranged further away from the display area DA than the first dam D1. In other words, the shortest distance between the second dam D2 and the display area DA may be longer than the shortest distance between the first dam D1 and the display area DA.

A recess V may be formed in the peripheral area PA of the display device 1. For example, the recess V may be arranged between the first dam D1 and the display area DA. As illustrated in FIG. 4, the recess V may have an island shape. In another embodiment, as illustrated in FIG. 5, the recess V may have a linear shape to extend along and parallel to the edge of the display area DA. However, the present disclosure is not limited thereto.

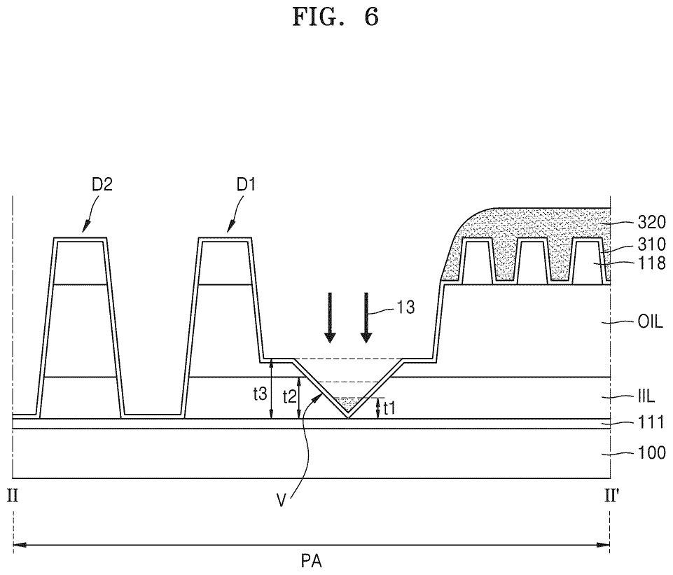

FIG. 6 is a schematic cross-sectional view of the peripheral areas of the display device taken along the line II-II′ in FIGS. 4 and 5.

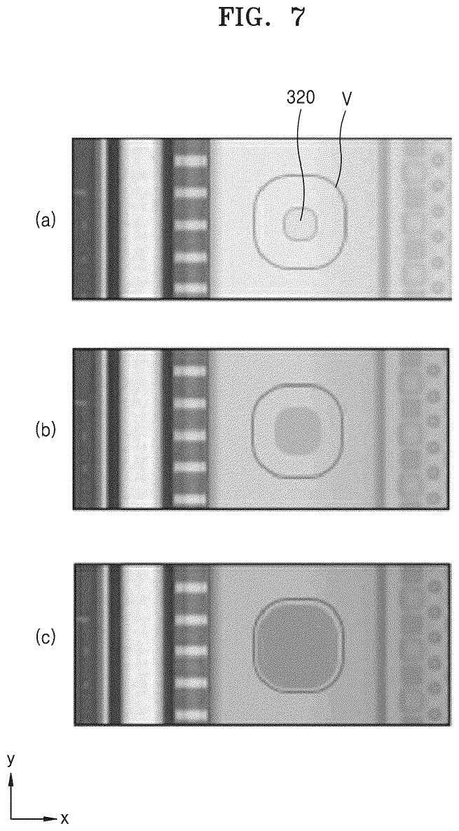

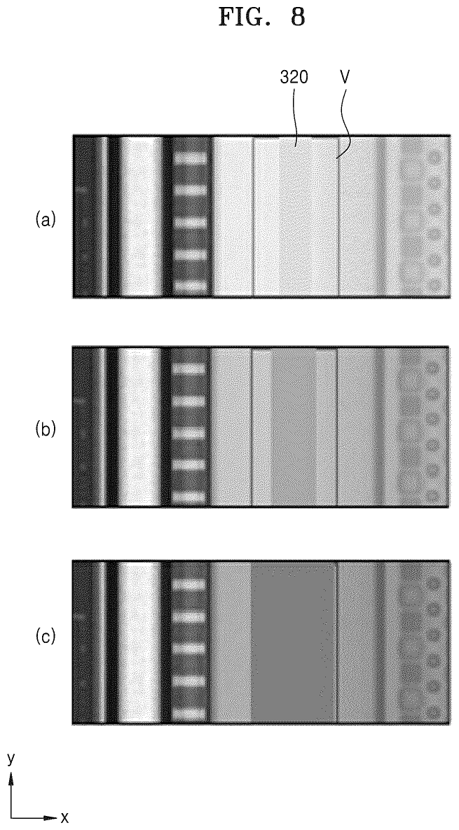

FIGS. 7 and 8 are images with schematic overlays showing organic encapsulation layers applied to peripheral areas of display devices according to some embodiments. In more detail, FIG. 7(a) and FIG. 8(a) show embodiments in which the thickness of the organic encapsulation layer 320 filled in the recess V is t1, FIG. 7(b) and FIG. 8(b) show embodiments in which the thickness of the organic encapsulation layer 320 filled in the recess V is t2, and FIG. 7(c) and FIG. 8(c) show embodiments in which the thickness of the organic encapsulation layer 320 filled in the recess V is t3.

Furthermore, FIGS. 7(a), 7(b), and 7(c) are images of the organic encapsulation layer 320 applied to an embodiment in which the recess V has an island shape (see, e.g., FIG. 4), and FIGS. 8(a), 8(b), and 8(c) are images of the organic encapsulation layer 320 applied to an embodiment in which the recess V has a linear shape (see, e.g., FIG. 5).

Referring to FIG. 6, the first dam D1 and the second dam D2 may be arranged in the peripheral area PA of the display device 1. The first dam D1 and the second dam D2 may each be provided as at least a part of the inorganic insulating layer IIL and as at least a part and the organic insulating layer OIL. Furthermore, the first dam D1 and the second dam D2 may each include at least a part of the pixel defining layer 118. However, the present disclosure is not limited thereto. At least a part of the spacer 119 may be arranged on top of the first dam D1 or the second dam D2.

The recess V may be arranged (or formed) between the first dam D1 and the display area DA (see, e.g., FIG. 1). The recess V may be a portion where at least a part of the inorganic insulating layer IIL or at least a part of the organic insulating layer OIL arranged in the peripheral area PA is removed. For example, the recess V may be a portion where at least a part of the inorganic insulating layer IIL or at least a part of the organic insulating layer OIL arranged between the first dam D1 and the display area DA is removed.

In an embodiment, the area of a cross-section (e.g., an x-y cross-section) of the recess V parallel to the substrate 100 may gradually decrease in a direction toward the substrate 100 (e.g., in a −z direction). In other words, in a cross-section (e.g., an x-z cross-section), the length of the recess V in a first direction (e.g., in an x direction or a −x direction) may uniformly decrease in the direction toward the substrate 100 (e.g., the −z direction). In other words, the recess V may narrow as it approaches the substrate 100.

In the peripheral area PA, the first inorganic encapsulation layer 310 may be continuously disposed on the substrate 100. The organic encapsulation layer 320 may be disposed on the first inorganic encapsulation layer 310. The organic encapsulation layer 320 may be filled in the recess V arranged in the peripheral area PA.

Referring to FIGS. 6 to 8, to estimate the application amount of the organic encapsulation layer 320 applied to the peripheral area PA, light 13 may be irradiated to the organic encapsulation layer 320. In more detail, the light 13 may be irradiated to estimate the application amount of the organic encapsulation layer 320 filled in the recess Vin the peripheral area PA. A method of estimating the application amount of the organic encapsulation layer 320 applied to the peripheral area PA may include applying the organic encapsulation layer 320 on the substrate 100 including the display area DA and the peripheral area PA surrounding at least a part of the display area DA, irradiating the light 13 to the organic encapsulation layer 320, and capturing an image of the peripheral area PA to which the organic encapsulation layer 320 is applied.

When the light 13 is irradiated to the organic encapsulation layer 320, which is transparent, the organic encapsulation layer 320 may become opaque. The light 13 may have a wavelength range in an ultraviolet region. In more detail, according to the Beer-Lambert law, the absorbance of the organic encapsulation layer 320 to ultraviolet rays may increase in proportion to an increase in the thickness of the organic encapsulation layer 320 applied to the peripheral area PA, and thus, a degree of opacity of the organic encapsulation layer 320 may increase. The degree of opacity of the organic encapsulation layer 320 may vary according to the thickness of the organic encapsulation layer 320 applied to the peripheral area PA.

In an embodiment, according to the degree of opacity of the organic encapsulation layer 320 to which the light 13 is irradiated, the thickness or application amount of the organic encapsulation layer 320 applied to the peripheral area PA may be estimated. In more detail, according to the degree of opacity of the organic encapsulation layer 320 to which the light 13 is irradiated, the thickness or application amount of the organic encapsulation layer 320 filled in the recess V of the peripheral area PA may be estimated. As the degree of opacity of the organic encapsulation layer 320 to which the light 13 is irradiated increases, the thickness of the organic encapsulation layer 320 formed in the peripheral area PA may increase. In other words, as the degree of opacity of the organic encapsulation layer 320 decreases, the thickness of the organic encapsulation layer 320 formed in the peripheral area PA may decrease.

In the irradiating of the light 13 to the organic encapsulation layer 320, the light 13 may have a wavelength range in an ultraviolet region. For example, the wavelength range of the light 13 may be in a range of about 365 nm to about 395 nm. When an ultraviolet ray in a wavelength range of about 365 nm to about 395 nm is irradiated to the transparent organic encapsulation layer 320, the organic encapsulation layer 320 may absorb the ultraviolet ray to become opaque. When the wavelength range of the light 13 is less than about 365 nm, the absorbance of the organic encapsulation layer 320 to light increases, which may cause a defect in a display device. When the wavelength range of the light 13 exceeds about 395 nm, the reflectivity of a lower wiring placed in the peripheral area PA to the light 13 increases, causing interference in the estimating of the application amount of the organic encapsulation layer 320 according to the degree of opacity of the organic encapsulation layer 320 in the peripheral area PA by capturing an image of the peripheral area PA, and thus, the estimating of the application amount of the organic encapsulation layer 320 may become difficult.

In an embodiment, the thickness of the organic encapsulation layer 320 filled in the recess V in the peripheral area PA may be t1, t2, or t3. From among the thicknesses of the organic encapsulation layer 320, t3 may be the largest, t1 may be the smallest, and t2 may be an amount between t1 and t3.

When the thickness of the organic encapsulation layer 320 filled in the recess V in the peripheral area PA is t3 (e.g., when the recess V is completely filled with the organic encapsulation layer 320), the absorbance of the organic encapsulation layer 320 to ultraviolet rays may be greater than the absorbance when the thickness of the organic encapsulation layer 320 is t1 or t2. In this case, when an image of the organic encapsulation layer 320 to which ultraviolet rays are irradiated is captured, the degree of opacity may be greater than the degree of opacity when the thickness of the organic encapsulation layer 320 is t1 or t2. FIGS. 7(c) and 8(c) are images of the organic encapsulation layer 320 to which ultraviolet rays are irradiated when the thickness of the organic encapsulation layer 320 filled in the recess V is t3. As can be seen, the degree of opacity of the organic encapsulation layer 320 filled in the recess V is greater that of FIGS. 7(a) and 7(b) and FIGS. 8(a) and 8(b).

When the thickness of the organic encapsulation layer 320 filled in the recess V in the peripheral area PA is t1, the absorbance of the organic encapsulation layer 320 to ultraviolet rays may be less than the absorbance when the thickness of the organic encapsulation layer 320 is t2 or t3. In this case, when an image of the organic encapsulation layer 320 to which ultraviolet rays are irradiated is captured, the degree of opacity may be less than the degree of opacity when the thickness of the organic encapsulation layer 320 is t2 or t3. FIGS. 7(a) and 8(a) are images of the organic encapsulation layer 320 to which ultraviolet rays are irradiated when the thickness of the organic encapsulation layer 320 filled in the recess V is t1. As can be seen, the degree of opacity of the organic encapsulation layer 320 filled in the recess V is less than that of FIGS. 7(b) and 7(c) and FIGS. 8(b) and 8(c).

Furthermore, when the thickness of the organic encapsulation layer 320 filled in the recess V in the peripheral area PA is t2, the absorbance of the organic encapsulation layer 320 to the ultraviolet ray may be in a range between the absorbance when the thickness of the organic encapsulation layer 320 is t1 and the absorbance when the thickness of the organic encapsulation layer 320 is t3. In this case, when an image of the organic encapsulation layer 320 to which ultraviolet rays are irradiated is captured, the degree of opacity may be between the opacity when the thickness of the organic encapsulation layer 320 is t1 and the opacity when the thickness of the organic encapsulation layer 320 is t3. FIGS. 7(b) and 8(b) are images of the organic encapsulation layer 320 to which ultraviolet rays are irradiated when the thickness of the organic encapsulation layer 320 filled in the recess V is t2. As can be seen, the degree of opacity of the organic encapsulation layer 320 filled in the recess V is between the opacity of FIGS. 7(a) and 8(a) and the opacity of FIGS. 7(c) and 8(c).

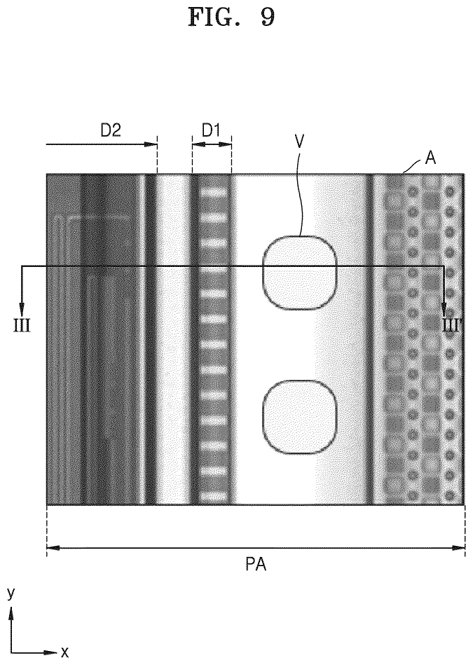

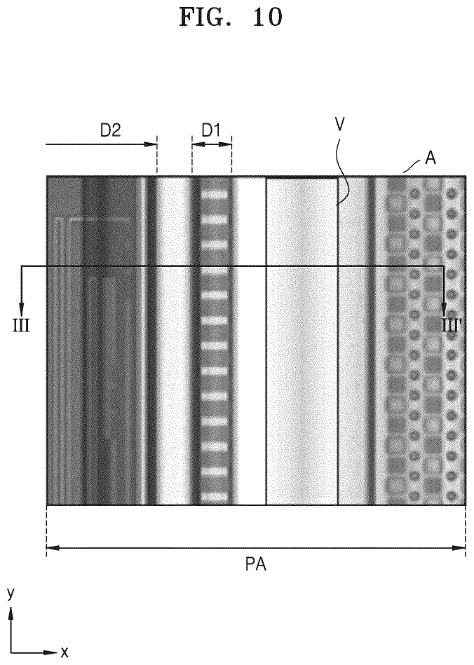

FIGS. 9 and 10 are images with schematic overlays showing an area A of the peripheral area PA of the display device 1 according to different embodiments.

Referring to FIGS. 9 and 10, the first dam D1 may be arranged in the peripheral area PA of the display device 1. The first dam D1 may be arranged along and parallel to the edge of the display area DA.

The recess V may be arranged in the peripheral area PA of the display device 1. In more detail, the recess V may be arranged between the first dam D1 and the display area DA. As illustrated in FIG. 9, the recess V may have an island shape. As illustrated in FIG. 10, the recess V may have a linear shape to be along and parallel to the edge of the display area DA. However, the present disclosure is not limited to these embodiments.

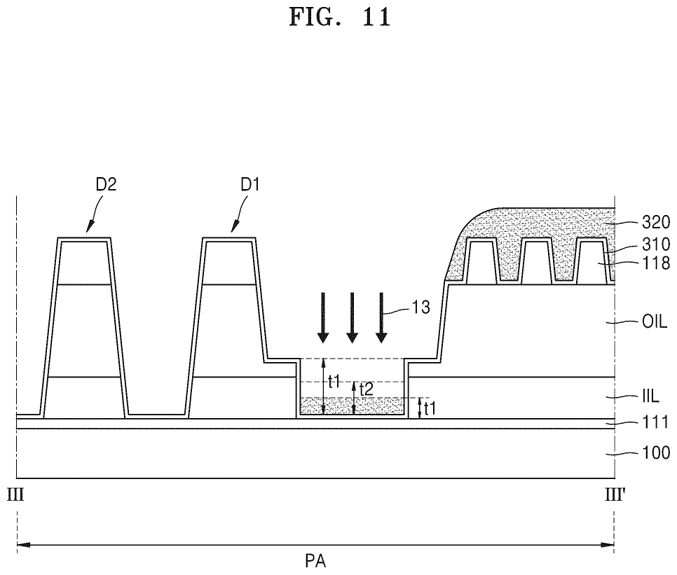

FIG. 11 is a schematic cross-sectional view of the peripheral areas PA of the display device taken along the line III-III′ in FIGS. 9 and 10.

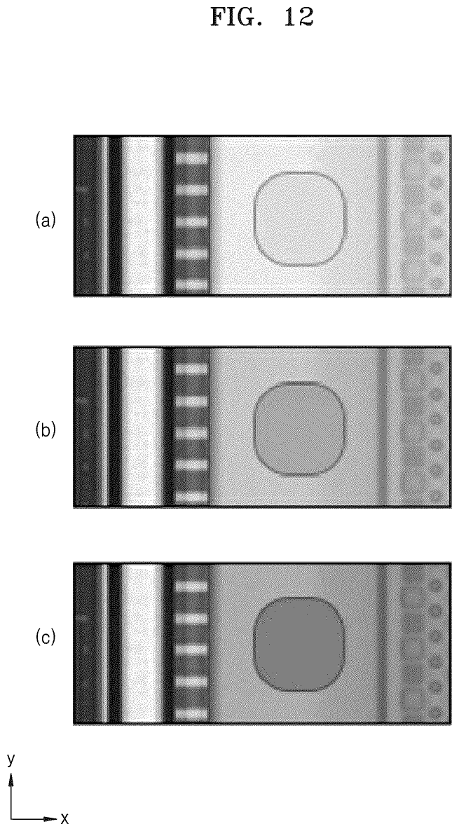

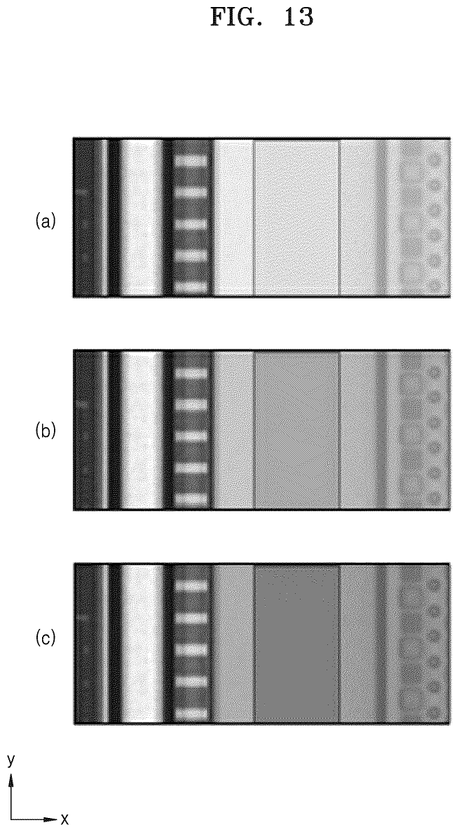

FIGS. 12(a), 12(b), and 12(c) and FIGS. 13(a), 13(b), and 13(c) are images with schematic overlays showing organic encapsulation layers applied to peripheral areas of display devices according to different embodiments. In more detail, FIGS. 12(a) and 13(a) show a case in which the thickness of the organic encapsulation layer 320 filled in the recess V is t1, FIGS. 12(b) and 13(b) show a case in which the thickness of the organic encapsulation layer 320 filled in the recess V is t2, and FIGS. 12(c) and 13(c) show a case in which the thickness of the organic encapsulation layer 320 filled in the recess V is t3.

FIGS. 12(a), 12(b), and 12(c) are images of the organic encapsulation layer 320 applied in an embodiment in which the recess V has an island shape, and FIGS. 13(a), 13(b), and 13(c) are images of the organic encapsulation layer 320 applied in an embodiment in which the recess V has a linear shape.

Referring to FIG. 11, the recess V may be arranged (or formed) between the first dam D1 and the display area DA. The recess V may be a portion where at least a part of the inorganic insulating layer IIL or at least a part of the organic insulating layer OIL arranged in the peripheral area PA is removed. In more detail, the recess V may be a portion where at least a part of the inorganic insulating layer IIL or at least a part of the organic insulating layer OIL arranged between the first dam D1 and the display area DA is removed.

In an embodiment, the area of a cross-section (e.g., an x-y cross-section) of the recess V parallel to the substrate 100 may be constant in a direction perpendicular to the substrate 100 (e.g., a z direction or a −z direction). In other words, in a cross-section (e.g., an x-z cross-section), the length of the recess V in a first direction (e.g., an x direction or a −x direction) may be constant. In other words, the recess V may have parallel or substantially parallel sidewalls.

In the peripheral area PA, the first inorganic encapsulation layer 310 may be continuously disposed on the substrate 100. The organic encapsulation layer 320 may be disposed on the first inorganic encapsulation layer 310. The organic encapsulation layer 320 may be filled in the recess V arranged in the peripheral area PA.

Referring to FIGS. 11 to 13, to estimate the application amount of the organic encapsulation layer 320 applied to the peripheral area PA, light 13 may be irradiated to the organic encapsulation layer 320. To estimate the application amount of the organic encapsulation layer 320 applied to the peripheral area PA, the method of estimating the application amount of the organic encapsulation layer 320 applied to the peripheral area PA may include applying the organic encapsulation layer 320 on the substrate 100 including the display area DA and the peripheral area PA surrounding at least a part of the display area DA, irradiating the light 13 to the organic encapsulation layer 320, and capturing an image of the peripheral area PA to which the organic encapsulation layer 320 is applied.

In an embodiment, the thickness of the organic encapsulation layer 320 filled in the recess V in the peripheral area PA may be t1, t2, or t3. From among the thicknesses of the organic encapsulation layer 320, t3 may be the largest, t1 may be the smallest, and t2 may be between t1 and t3.

When the thickness of the organic encapsulation layer 320 filled in the recess V in the peripheral area PA is t3, the absorbance of the organic encapsulation layer 320 to ultraviolet rays may be greater than the absorbance when the thickness of the organic encapsulation layer 320 is t1 or t2. In this case, when an image of the organic encapsulation layer 320 to which ultraviolet rays are irradiated is captured, the degree of opacity may be greater than the degree of opacity when the thickness of the organic encapsulation layer 320 is t1 or t2. FIGS. 12(c) and 13(c) are images of the organic encapsulation layer 320 to which ultraviolet rays are irradiated when the thickness of the organic encapsulation layer 320 filled in the recess V is t3. As can be seen, the degree of opacity of the organic encapsulation layer 320 filled in the recess V is greater than as shown in FIGS. 12(a) and 12(b) and FIGS. 13(a) and 13(b).

When the thickness of the organic encapsulation layer 320 filled in the recess V in the peripheral area PA is t1, the absorbance of the organic encapsulation layer 320 to ultraviolet rays may be less than the absorbance when the thickness of the organic encapsulation layer 320 is t2 or t3. In this case, when an image of the organic encapsulation layer 320 to which ultraviolet rays are irradiated is captured, the degree of opacity may be less than the degree of opacity when the thickness of the organic encapsulation layer 320 is t2 or t3. FIGS. 12(a) and 13(a) are images of the organic encapsulation layer 320 to which ultraviolet rays are irradiated when the thickness of the organic encapsulation layer 320 filled in the recess V is t1. As can be seen, the degree of opacity of the organic encapsulation layer 320 filled in the recess V is less than as shown in FIGS. 12(b) and 12(c) and FIGS. 13(b) and 13(c).

Furthermore, when the thickness of the organic encapsulation layer 320 filled in the recess V in the peripheral area PA is t2, the absorbance of the organic encapsulation layer 320 to the ultraviolet ray may be between the absorbance when the thickness of the organic encapsulation layer 320 is t1 and the absorbance when the thickness of the organic encapsulation layer 320 is t3. In this state, when an image of the organic encapsulation layer 320 to which ultraviolet rays are irradiated is captured, the degree of opacity may be between the opacity when the thickness of the organic encapsulation layer 320 is t1 and the opacity when the thickness of the organic encapsulation layer 320 is t3. FIGS. 12(b) and 13(b) are images of the organic encapsulation layer 320 to which ultraviolet rays are irradiated when the thickness of the organic encapsulation layer 320 filled in the recess V is t2. As can be seen, the degree of opacity of the organic encapsulation layer 320 filled in the recess V is between the opacity shown in FIGS. 12(a) and 13(a) and the opacity of FIGS. 12(c) and 13(c).

When the organic encapsulation layer 320 is applied to (or extends to) the outer edge of the first dam D1 in the peripheral area PA of the display device 1, the organic encapsulation layer 320 may become a moisture penetration path of the display device 1, and thus, a defect may occur in the display device 1. Accordingly, it may be important in a manufacturing method to estimate the application amount of the organic encapsulation layer 320 applied to the peripheral area PA of the display device 1.

When the organic encapsulation layer 320 is filled in the recess V between the first dam D1 and the display area DA, because the organic encapsulation layer 320 is a fluid having a spreading property, it is difficult to estimate specific thickness and application amount of how much the organic encapsulation layer 320 is filled in the recess V.

In an embodiment, according to the degree of opacity of the organic encapsulation layer 320 to which ultraviolet rays are irradiated, the thickness and application amount of the organic encapsulation layer 320 applied to the peripheral area PA (e.g., filled in the recess V) may be estimated. In an image of the organic encapsulation layer 320, the thickness and application amount of the organic encapsulation layer 320 may be precisely estimated according to the degree of opacity of the organic encapsulation layer 320, and before forming the second inorganic encapsulation layer 330 on the organic encapsulation layer 320, a degree of ashing may be estimated in detail in a process of ashing at least a part of the organic encapsulation layer 320. Thus, efficiency and reliability may be improved in a process of manufacturing the display device 1.

As described above, according to an embodiment, a method of manufacturing a display device with improved efficiency and reliability may be implemented. The scope of the present disclosure is not limited by the above aspects and features.

It should be understood that the embodiments described herein should be considered in a descriptive sense and not for purposes of limitation. Descriptions of features or aspects within each embodiment should typically be considered as available for other similar features or aspects in other embodiments. While embodiments of the present disclosure have been described with reference to the figures, it will be understood by those of ordinary skill in the art that various changes in form and details may be made therein without departing from the spirit and scope as defined by the following claims and their equivalents.

What is claimed is:

1. A method of manufacturing a display device, the method comprising:
applying an organic encapsulation layer to a substrate of the display device, the substrate having a display area and a peripheral area extending at least partially around the display area;
irradiating light to the organic encapsulation layer; and
capturing an image of the peripheral area to which the organic encapsulation layer is applied.

2. The method of claim 1, further comprising, after the capturing of the image of the peripheral area, estimating an application amount of the organic encapsulation layer applied to the peripheral area.

3. The method of claim 1, wherein, in the irradiating of the light to the organic encapsulation layer, the organic encapsulation layer to which the light is irradiated becomes opaque.

4. The method of claim 3, wherein an application amount of the organic encapsulation layer is estimated according to a degree of opacity of the organic encapsulation layer to which the light is irradiated.

5. The method of claim 3, wherein a degree of opacity of the organic encapsulation layer varies according to a thickness of the organic encapsulation layer that is applied.

6. The method of claim 5, wherein, as a thickness of the organic encapsulation layer that is applied increases, the degree of opacity of the organic encapsulation layer increases.

7. The method of claim 1, wherein the light has a wavelength range in an ultraviolet region.

8. The method of claim 7, wherein the wavelength range of the light is from 365 nm to 395 nm.

9. The method of claim 1, wherein the display device comprises a first dam in the peripheral area.

10. The method of claim 9, wherein the display device has a recess in the peripheral area between the first dam and the display area.

11. The method of claim 10, wherein the display device further comprises a second dam in the peripheral area and further away from the display area than the first dam is.

12. The method of claim 10, wherein, in the applying of the organic encapsulation layer to the substrate, the organic encapsulation layer is filled in the recess.

13. The method of claim 10, wherein an area of a cross-section of the recess parallel to the substrate decreases in a direction toward the substrate.

14. The method of claim 10, wherein a cross-sectional length of the recess in a first direction uniformly decreases in a direction toward the substrate.

15. The method of claim 13, wherein the recess has an island shape.

16. The method of claim 13, wherein the recess has a linear shape and extends parallel to an edge of the display area.

17. The method of claim 10, wherein a cross-sectional area of the recess parallel to the substrate is constant in a direction perpendicular to the substrate.

18. The method of claim 10, wherein a cross-sectional length of the recess in a first direction is constant.

19. The method of claim 17, wherein the recess has an island shape.

20. The method of claim 17, wherein the recess has a linear shape and extends parallel to an edge of the display area.
